(19) United States
(12) Patent Application Publication
(10) Pub. No.: US 2025/0047250 A1
(43) Pub. Date: Feb. 6, 2025

(54) RADIO FREQUENCY CIRCUIT AND COMMUNICATION DEVICE

(71) Applicant: Murata Manufacturing Co., Ltd., Nagaokakyo-shi (JP)

(72) Inventors: Kenji TAHARA, Nagaokakyo-shi (JP); Ryo WAKABAYASHI, Nagaokakyo-shi (JP); Kae YAMAMOTO, Nagaokakyo-shi (JP); Toshiki MATSUI, Nagaokakyo-shi (JP)

(73) Assignee: Murata Manufacturing Co., Ltd., Nagaokakyo-shi (JP)

(21) Appl. No.: 18/922,573

(22) Filed: Oct. 22, 2024

Related U.S. Application Data
(63) Continuation of application No. PCT/JP2023/006218, filed on Feb. 21, 2023.

(30) Foreign Application Priority Data
Apr. 22, 2022 (JP) 2022-070683

(51) Int. Cl. H03F 3/24; H03F 1/02; H04B 1/04

(52) U.S. Cl. CPC H03F 3/245; H03F 1/0288; H04B 1/04; H03F 2200/451

(57) ABSTRACT

A radio frequency circuit that includes a carrier amplifier, a transmission line transformer having a main line and a sub line, a signal output terminal, a voltage supply terminal and a capacitor, wherein the main line has one end connected to an output end of a peak amplifier, the main line has another end connected to the signal output terminal, the sub line has one end connected to the one end of the main line, the sub line has another end connected to the voltage supply terminal, and the peak amplifier has the output end connected to the voltage supply terminal with the capacitor interposed therebetween.

### CROSS-REFERENCE TO RELATED APPLICATIONS

This is a continuation application of PCT/JP2023/006218, filed on Feb. 21, 2023, designating the United States of America, which is based on and claims priority to Japanese Patent Application No. JP 2022-070683 filed on Apr. 22, 2022. The entire contents of the above-identified applications, including the specifications, drawings and claims, are incorporated herein by reference in their entirety.

### TECHNICAL FIELD

The present disclosure relates to a radio frequency circuit and a communication device.

### BACKGROUND ART

Patent Document 1 discloses an amplifier circuit (radio frequency circuit) including a transmission line transformer and a power amplifier. The transmission line transformer is connected to an output terminal of an amplification element, and includes two primary side transmission lines and one secondary side transmission line.

### CITATION LIST

### Patent Document

Patent Document 1: Japanese Unexamined Patent Application Publication No. 2006-295896

### SUMMARY OF DISCLOSURE

### Technical Problem

In the configuration in Patent Document 1, for example, a configuration is conceivable in which, in order to improve linearity of a high-output radio frequency signal, a harmonic termination circuit is disposed. However, assuming the harmonic termination circuit is simply added, the radio frequency circuit may be increased in size.

The present disclosure has been made to solve the above problem, and an feature of the present disclosure is to provide a radio frequency circuit and a communication device that are compact and in which harmonic waves are suppressed.

### Solution to Problem

In order to achieve the above purpose, a radio frequency circuit according to an aspect of the present disclosure includes a first amplification element, a transmission line transformer having a main line and a sub line, a signal output terminal, a voltage supply terminal, and a first capacitor, wherein one end of the main line is connected to an output end of the first amplification element, and another end of the main line is connected to the signal output terminal, one end of the sub line is connected to the one end of the main line, another end of the sub line is connected to the voltage supply terminal, and the output end of the first amplification element is connected to the voltage supply terminal with the first capacitor interposed therebetween.

### Advantageous Effects of Disclosure

According to the present disclosure, it is possible to provide a radio frequency circuit and a communication device that are compact and in which harmonic waves are suppressed.

### BRIEF DESCRIPTION OF DRAWINGS

FIG. 1 is a circuit configuration diagram of a radio frequency circuit and a communication device according to an embodiment.

FIG. 2 is a circuit configuration diagram of an amplifier circuit according to a comparative example.

FIG. 3A is a graph showing transmission characteristics of an amplifier circuit according to the embodiment.

FIG. 3B is a graph showing transmission characteristics of the amplifier circuit according to the comparative example.

FIG. 4A includes plan views and a sectional view of the amplifier circuit according to the embodiment.

FIG. 4B includes plan views and a sectional view of the amplifier circuit according to the comparative example.

FIG. 5A includes plan views of an amplifier circuit according to Modification 1.

FIG. 5B includes plan views of an amplifier circuit according to Modification 2.

FIG. 6 is a circuit configuration diagram of a radio frequency circuit and a communication device according to Modification 3.

### DESCRIPTION OF EMBODIMENTS

Hereinafter, an embodiment of the present disclosure will be described in detail using the drawings. Note that the embodiment described below is a comprehensive or specific example. Numerical values, shapes, materials, components, dispositions and connection forms of the components, and the like illustrated in the following embodiment are mere examples, and are not intended to limit the present disclosure.

Note that each drawing is a schematic view in which emphasis, omission, or adjustment of ratios is performed as appropriate in order to illustrate the present disclosure, and is not necessarily illustrated strictly, and shapes, positional relationships, and ratios may be different from actual ones. In each drawing, substantially the same configurations are denoted by the same reference numerals, and redundant description may be omitted or simplified.

In the present disclosure, “connected” is not only a case of direct connection by a connection terminal and/or a wiring conductor but also a case of electrical connection via another circuit element. Further, “connected to A and B therebetween” corresponds to a state of being connected to A and B on a path connecting A and B.

In addition, in the present disclosure, “in plan view” corresponds to a state where an feature is viewed while being orthographically projected on an xy plane from a positive direction side of a z-axis. “A component is disposed at a main surface of a substrate” includes a case where the component is disposed on the main surface in a state of being in contact with the main surface of the substrate, a case where the component is disposed above the main surface without being in contact with the main surface, and a case where the component is disposed with a part thereof embedded in the substrate from a side of the main surface.

In addition, in a component disposition of the present disclosure, among A, B, and C disposed at a substrate, “C is disposed between A and B” corresponds to a state where at least one line segment of a plurality of line segments connecting any point inside A and any point inside B passes through a region of C.

In addition, in a component disposition of the present disclosure, “A and B are adjacent to each other” corresponds to a state where A and B are disposed close to each other, and specifically corresponds to a state where no circuit component is present in a facing space between A and B. In other words, it corresponds to a state where no line segment of a plurality of line segments starting from any points on a surface of A facing B and reaching B in a direction normal to the surface passes through circuit components other than A and B. Note that the circuit components include active components such as transistors and diodes, and passive components such as inductors, transformers, capacitors and resistors, and do not include terminals, connectors, electrodes, wiring lines, resin members, or the like.

In addition, in the present disclosure, a “signal path” corresponds to a transmission line constituted by a wiring line through which a radio frequency signal propagates, an electrode directly connected to the wiring line, a terminal directly connected to the wiring line or the electrode, and the like.

### Embodiment

### [1. Circuit Configuration of Radio Frequency Circuit 1 and Communication Device 5]

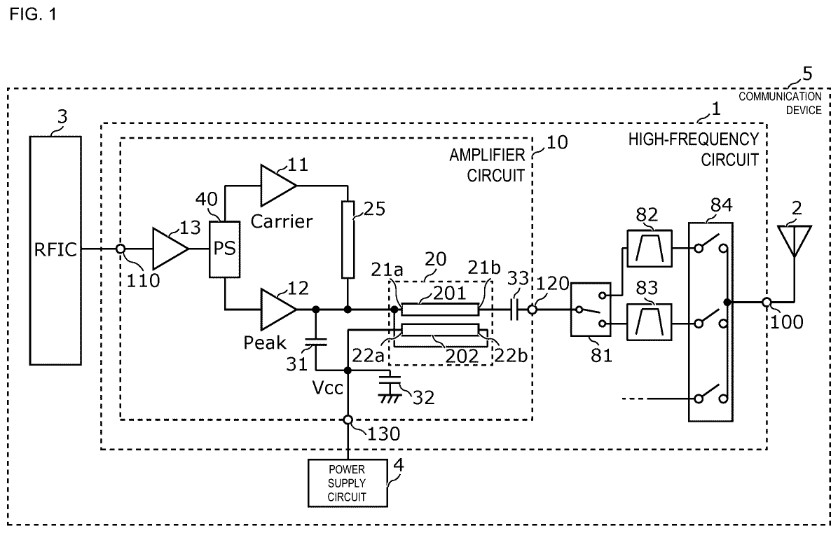

A circuit configuration of the radio frequency circuit 1 and the communication device 5 according to the present embodiment will be described with reference to FIG. 1. FIG. 1 is a circuit configuration diagram of the radio frequency circuit 1 and the communication device 5 according to the embodiment.

### [1.1 Circuit Configuration of Communication Device 5]

First, a circuit configuration of the communication device 5 will be described. As illustrated in FIG. 1, the communication device 5 according to the present embodiment includes the radio frequency circuit 1, an antenna 2, an RF signal processing circuit (RFIC) 3, and a power supply circuit 4.

The radio frequency circuit 1 transmits a radio frequency signal between the antenna 2 and the RFIC 3. A detailed circuit configuration of the radio frequency circuit 1 will be described later.

The antenna 2 is connected to an antenna connection terminal 100 of the radio frequency circuit 1, transmits a radio frequency signal outputted from the radio frequency circuit 1. The antenna 2 also receives a radio frequency signal from outside and outputs the radio frequency signal to the radio frequency circuit 1.

The RFIC 3 is an example of a signal processing circuit that processes a radio frequency signal. To be more specific, the RFIC 3 applies signal processing to a reception signal received via a receive path of the radio frequency circuit 1 by down-conversion or the like, and outputs a reception signal generated by the signal processing to a baseband signal processing circuit (BBIC, not illustrated). Further, the RFIC 3 applies signal processing to a transmission signal received from the BBIC by up-conversion or the like and outputs a transmission signal generated by the signal processing to a transmission path of the radio frequency circuit 1. Further, the RFIC 3 has a control unit that controls switches, amplifiers, and the like included in the radio frequency circuit 1. Note that some or all of functions as the control unit of the RFIC 3 may be implemented outside the RFIC 3, and may be implemented in the BBIC or the radio frequency circuit 1, for example.

Further, the RFIC 3 also has a function as the control unit that controls a power supply voltage Vcc supplied to each amplifier included in the radio frequency circuit 1. In particular, the RFIC 3 outputs a digital control signal to the power supply circuit 4. The power supply voltage Vcc controlled by the digital control signal is supplied from the power supply circuit 4 to each amplifier of the radio frequency circuit 1.

Further, the RFIC 3 also functions as the control unit that controls connection at switches 81 and 84 included in the radio frequency circuit 1 based on a communication band (frequency band) used.

The power supply circuit 4 supplies the power supply voltage Vcc to each amplifier of the radio frequency circuit 1 based on a digital control signal outputted from the RFIC 3. Note that the power supply circuit 4 may be disposed in the radio frequency circuit 1 or an amplifier circuit 10.

In addition, in the communication device 5 according to the present embodiment, the antenna 2 is not an essential component.

### [1.2 Circuit Configuration of Radio Frequency Circuit 1]

Next, a circuit configuration of the radio frequency circuit 1 will be described. As illustrated in FIG. 1, the radio frequency circuit 1 includes the amplifier circuit 10, filters 82 and 83, the switches 81 and 84 and the antenna connection terminal 100.

The amplifier circuit 10 is a circuit that amplifies radio frequency transmission signals (hereinafter referred to as transmission signals) in a band A and a band B received from a signal input terminal 110. Note that the radio frequency circuit 1 may include a first amplifier circuit that amplifies a transmission signal in the band A and a second amplifier circuit that amplifies a transmission signal in the band B, instead of the amplifier circuit 10.

Note that in the present embodiment, each of the band A and the band B corresponds to a frequency band that is predefined by a standardizing body (for example, 3GPP (registered trademark) (3rd Generation Partnership Project), IEEE (Institute of Electrical and Electronics Engineers), or the like) or the like for a communication system constructed using a radio access technology (RAT). In the present embodiment, as the communication system, for example, a 4G (4th Generation)-LTE (Long Term Evolution) system, a 5G (5th Generation)-NR (New Radio) system, a WLAN (Wireless Local Area Network) system, or the like can be used, but the communication system is not limited thereto.

The filter 82 is connected to the switches 81 and 84 therebetween and passes a transmission signal in a transmission band in the band A among the transmission signals amplified by the amplifier circuit 10. Further, the filter 83 is connected to the switches 81 and 84 therebetween and passes a transmission signal in a transmission band in the band B among the transmission signals amplified by the amplifier circuit 10.

Note that each of the filters 82 and 83 may constitute a duplexer together with a reception filter, or may be a single filter that performs transmission using a time division duplex (TDD) method. Assuming the filters 82 and 83 are TDD filters, a switch for switching between transmission and reception is disposed in at least one of a preceding stage and a subsequent stage of the single filter.

The switch 81 has a common terminal, a first selection terminal, and a second selection terminal. The common terminal is connected to a signal output terminal 120 of the amplifier circuit 10. The first selection terminal is connected to the filter 82, and the second selection terminal is connected to the filter 83. In this connection configuration, the switch 81 switches between connection between the amplifier circuit 10 and the filter 82 and connection between the amplifier circuit 10 and the filter 83.

The switch 84 is an example of an antenna switch and is connected to the antenna connection terminal 100 to switch between connection and disconnection between the antenna connection terminal 100 and the filter 82, and to switch between connection and disconnection between the antenna connection terminal 100 and the filter 83.

Note that the radio frequency circuit 1 may include a receiving circuit for transmitting a reception signal received from the antenna 2 to the RFIC 3. In this case, the radio frequency circuit 1 includes a low-noise amplifier and a reception filter.

Additionally, an impedance matching circuit may be disposed on a path from the signal output terminal 120 to the antenna connection terminal 100.

According to the above circuit configuration, the radio frequency circuit 1 can transmit or receive a radio frequency signal in either the band A or the band B. Furthermore, the radio frequency circuit 1 can also perform at least one of simultaneous transmission, simultaneous reception, and simultaneous transmission and reception for radio frequency signals in the band A and the band B.

Note that it is sufficient that the radio frequency circuit 1 according to the present disclosure has at least the amplifier circuit 10 in the circuit configuration illustrated in FIG. 1.

Here, a circuit configuration of the amplifier circuit 10 will be described in detail.

As illustrated in FIG. 1, the amplifier circuit 10 includes a carrier amplifier 11, a peak amplifier 12, a preamplifier 13, a phase shift circuit 40, a transmission line transformer 20, a phase shift line 25, capacitors 31, 32, and 33, the signal input terminal 110, the signal output terminal 120, and a voltage supply terminal 130. The amplifier circuit 10 according to the present embodiment is a Doherty amplifier circuit having the carrier amplifier and the peak amplifier.

Note that the Doherty amplifier circuit corresponds to an amplifier circuit that achieves high efficiency by using a plurality of amplification elements as carrier amplifiers and peak amplifiers. A carrier amplifier corresponds to, in a Doherty-type amplifier circuit, an amplification element that operates regardless of whether power of a radio frequency signal (input) is low or high. A peak amplifier corresponds to, in a Doherty-type amplifier circuit, an amplification element that mainly operates assuming power of a radio frequency signal (input) is high. Thus, assuming input power of a radio frequency signal is low, the radio frequency signal is amplified mainly by the carrier amplifier, and assuming input power of radio frequency signals is high, the radio frequency signals are amplified by the carrier amplifier and the peak amplifier and combined. By such operation, in the Doherty-type amplifier circuit, a load impedance viewed from the carrier amplifier increases at low output power, and efficiency at low output power is improved.

In the radio frequency circuit according to the present disclosure, a phase shift circuit for shifting a phase of a radio frequency signal by ¼ of a wavelength is connected to an output end of the carrier amplifier 11.

The signal input terminal 110 is connected to the RFIC 3. The signal output terminal 120 is connected to the antenna connection terminal 100 with the switches 81 and 84 and the filters 82 and 83 interposed therebetween. The voltage supply terminal 130 is connected to the power supply circuit 4. Note that each of the signal input terminal 110, the signal output terminal 120, the antenna connection terminal 100, and the voltage supply terminal 130 may be a metal conductor such as a metal electrode or a metal bump, or may be one point on a metal wiring line.

The preamplifier 13 amplifies transmission signals in the band A and/or the band B received from the signal input terminal 110.

The phase shift circuit 40 distributes a signal RF0 outputted from the preamplifier 13 and outputs distributed signals RF1 and RF2 to the carrier amplifier 11 and the peak amplifier 12, respectively. At that time, the phase shift circuit 40 adjusts phases of the signals RF1 and RF2. For example, the phase shift circuit 40 shifts the phase of the signal RF2 by −90 degrees (delays the shift by 90 degrees) with respect to the shift of the signal RF1.

Note that the configurations of the preamplifier 13 and the phase shift circuit 40 are not limited to the above-described configurations. For example, the preamplifiers 13 may be disposed at each front stage of the carrier amplifier 11 and the peak amplifier 12. In this case, the phase shift circuits 40 may be disposed at each front stage of preamplifiers, or at each front stage of the carrier amplifier 11 and the peak amplifier 12. Further, the amplifier circuit 10 need not include the preamplifier 13 or the phase shift circuit 40.

Each of the carrier amplifier 11 and the peak amplifier 12 has an amplification transistor. The amplification transistor is, for example, a bipolar transistor such as a heterojunction bipolar transistor (HBT) or a field effect transistor such as a metal-oxide-semiconductor field effect transistor (MOSFET).

The carrier amplifier 11 is an example of a second amplification element and amplifies a transmission signal in the band A or the band B inputted to the carrier amplifier 11. The carrier amplifier 11 is, for example, a class A (or class AB) amplifier circuit capable of performing amplification operation on all power levels of signals inputted to the carrier amplifier 11 and is capable of performing highly efficient amplification operation particularly in a low output region and a medium output region.

The peak amplifier 12 is an example of a first amplification element and amplifies a transmission signal in the band A or the band B inputted to the peak amplifier 12. The peak amplifier 12 is, for example, a class C amplifier circuit that can perform amplification operation in a region where a power level of a signal inputted to the peak amplifier 12 is high. A bias current smaller than a bias current applied to the amplification transistor included in the carrier amplifier 11 may be applied to the amplification transistor included in the peak amplifier 12. According to this, an output impedance decreases as a power level of a signal inputted to the peak amplifier 12 increases. Thus, the peak amplifier 12 can perform amplification operation with low distortion in a high output region.

The phase shift line 25 is an example of a first phase shift circuit and is connected to the output end of the carrier amplifier 11 and an output end of the peak amplifier 12 therebetween. One end of the phase shift line 25 is connected to the output end of the carrier amplifier 11, and another end is connected to the output end of the peak amplifier 12. The phase shift line 25 shifts a phase of a signal outputted from the carrier amplifier 11 by −90 degrees (delays the phase by 90 degrees). Since the phase shift line 25 is disposed, a phase of a signal outputted from the carrier amplifier 11 and a phase of a signal outputted from the peak amplifier 12 are aligned. Thus, the signal outputted from the carrier amplifier 11 and the signal outputted from the peak amplifier 12 are subjected to current combination.

The transmission line transformer 20 has a main line 201 and a sub line 202, shifts phases at both ends of the transmission line transformer 20, and performs impedance conversion at a predetermined conversion ratio. The main line 201 is a transmission line, for example, having a length of ⅛ of a wavelength or 1/16 of a wavelength. One end 21a of the main line 201 is connected to the output end of the peak amplifier 12, and another end 21b of the main line 201 is connected to the signal output terminal 120 with the capacitor 33 interposed therebetween. The sub line 202 is a transmission line, for example, having a length of ⅛ of a wavelength or 1/16 of a wavelength. One end 22b of the sub line 202 is connected to the one end 21a of the main line 201, and another end 22a of the sub line 202 is connected to the voltage supply terminal 130.

Note that it is desirable that a first direction from the one end 21a to the other end 21b of the main line 201 is the same as a second direction from the other end 22a to the one end 22b of the sub line 202. In the above-described configuration, the main line 201 and the sub line 202 are electromagnetically coupled to each other.

The capacitor 31 is an example of a first capacitor and has one end connected to the output end of the peak amplifier 12 and another end connected to the voltage supply terminal 130. That is, the output end of the peak amplifier 12 is connected to the voltage supply terminal 130 with the capacitor 31 interposed therebetween.

The capacitor 32 is an example of a second capacitor and has one end connected to the voltage supply terminal 130 and another end connected to a ground. The capacitor 32 is a so-called bypass capacitor for suppressing a voltage fluctuation of the power supply voltage Vcc supplied via the voltage supply terminal 130.

Note that a capacitance value of the capacitor 31 is smaller than a capacitance value of the capacitor 32. According to this, since the capacitance value of the capacitor 31 can be made relatively small, deterioration of characteristics of a fundamental wave of a radio frequency signal can be suppressed.

The capacitor 33 has one end connected to the transmission line transformer 20 and another end connected to the signal output terminal 120, and prevents the power supply voltage Vcc being a DC supply voltage from leaking toward the switch 81 beyond the signal output terminal 120.

According to the above-described configuration of the amplifier circuit 10, an output impedance of the carrier amplifier 11 is increased assuming a small signal is inputted as compared to a situation where a large signal is inputted. That is, assuming a small signal is inputted, the peak amplifier 12 is brought into an off state, and the output impedance of the carrier amplifier 11 is increased, so that the amplifier circuit 10 can operate with high efficiency.

On the other hand, assuming a large signal is inputted, the carrier amplifier 11 and the peak amplifier 12 operate, and thus a large power signal can be outputted and an output impedance of the peak amplifier 12 is decreased, thus signal distortion can be suppressed.

In addition, in the amplifier circuit 10 according to the present embodiment, instead of the ¼ wavelength transmission line, the transmission line transformer 20 formed of a line shorter than ¼ of the wavelength is disposed, and thus the radio frequency circuit 1 can be miniaturized.

Note that the amplifier circuit 10 according to the present embodiment is not limited to the Doherty-type amplifier circuit. The amplifier circuit 10 according to the present embodiment need not include, for example, the preamplifier 13, the phase shift circuit 40, the carrier amplifier 11, or the phase shift line 25.

### [1.3 Circuit Configuration of Amplifier Circuit 510 According to Comparative Example]

Next, a circuit configuration of a Doherty-type amplifier circuit 510 in the related art will be described.

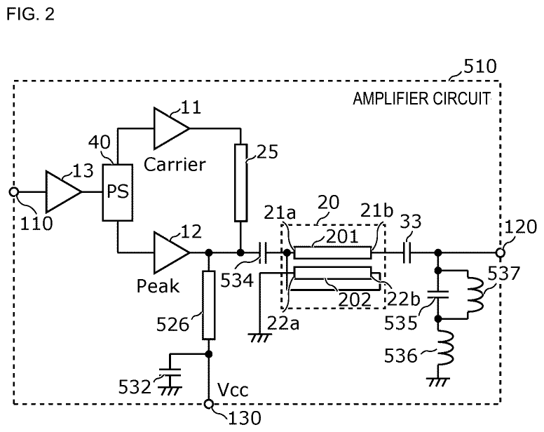

FIG. 2 is a circuit configuration diagram of the amplifier circuit 510 according to a comparative example. The amplifier circuit 510 includes the carrier amplifier 11, the peak amplifier 12, the preamplifier 13, the phase shift circuit 40, the transmission line transformer 20, the phase shift line 25 and a phase shift line 526, the capacitor 33, capacitors 532, 534, and 535, inductors 536 and 537, the signal input terminal 110, the signal output terminal 120, and the voltage supply terminal 130. The amplifier circuit 510 according to the comparative example is different from the amplifier circuit 10 according to the embodiment mainly in a configuration of a harmonic termination circuit and a configuration of voltage supply to the peak amplifier 12. The circuit configuration of the amplifier circuit 510 according to the comparative example will be described below, focusing on a configuration different from that of the amplifier circuit 10 according to the embodiment.

The transmission line transformer 20 has the main line 201 and the sub line 202, shifts phases at both ends of the transmission line transformer 20, and performs impedance conversion at a predetermined conversion ratio. The main line 201 is a transmission line, for example, having a length of ⅛ of a wavelength or 1/16 of a wavelength. The one end 21a of the main line 201 is connected to the output end of the peak amplifier 12 with the capacitor 534 interposed therebetween, and the other end 21b of the main line 201 is connected to the signal output terminal 120 with the capacitor 33 interposed therebetween. The sub line 202 is a transmission line, for example, having a length of ⅛ of a wavelength or 1/16 of a wavelength. The one end 22b of the sub line 202 is connected to the one end 21a of the main line 201, and the other end 22a of the sub line 202 is connected to the ground.

In the above-described configuration, the main line 201 and the sub line 202 are electromagnetically coupled to each other.

The phase shift line 526 has one end connected to the output end of the peak amplifier 12 and another end connected to the voltage supply terminal 130. The phase shift line 526 is, for example, a ¼ wavelength transmission line and has a function of bringing the output impedance of the peak amplifier 12 into an open state.

The capacitor 532 has one end connected to the voltage supply terminal 130 and another end connected to the ground. The capacitor 532 is a so-called bypass capacitor for suppressing a voltage fluctuation of the power supply voltage Vcc supplied via the voltage supply terminal 130.

The inductor 537 and the capacitor 535 constitute a parallel connection circuit. The parallel connection circuit and the inductor 536 constitute a series connection circuit. One end of the series connection circuit is connected to a node on a path connecting the transmission line transformer 20 and the signal output terminal 120, and another end of the series connection circuit is connected to the ground.

The capacitor 535 and the inductors 536 and 537 constitute the harmonic termination circuit. An LC series resonant circuit of the capacitor 535 and the inductor 536, at the node, has a function of making fundamental wave impedances of output signals from the carrier amplifier 11 and the peak amplifier 12 appear to be in the open state and making a second harmonic appear to be short to cause the amplifier to perform class F operation, but an insertion loss slightly occurs in a fundamental wave band. On the other hand, according to the harmonic termination circuit in which the inductor 537 is connected in parallel to the capacitor 535, by adjusting an inductance value of the inductor 537, the LC series resonant circuit can be made to appear open in the fundamental wave band, and the LC series resonant circuit can be made to appear short in a second harmonic frequency band due to capacitance of the capacitor 535. According to this, a bandpass characteristic can be improved such that an insertion loss in the second harmonic frequency band is large and an insertion loss in the fundamental wave band is minimized.

### [1.4 Circuit Configuration Comparison Between Amplifier Circuit 10 and Amplifier Circuit 510]

In the amplifier circuit 510, both the output end of the peak amplifier 12 and a node to which the harmonic termination circuit is connected need to be in the open state with respect to a fundamental wave. In view of this point, in the amplifier circuit 10, the inductor 537 of the harmonic termination circuit is substituted by the sub line 202, and the capacitor 535 of the harmonic termination circuit is diverted to the capacitor 31. Thus, in the amplifier circuit 10, an LC parallel resonant circuit constituted by the sub line 202 and the capacitor 31 is connected to the output end of the peak amplifier 12 and the voltage supply terminal 130 therebetween and functions as a harmonic termination circuit. Thus, in the amplifier circuit 10, the sub line 202 is used as a line for supplying the power supply voltage Vcc, which makes the capacitor 534 for DC blocking disposed in the amplifier circuit 510 unnecessary. In addition, in the amplifier circuit 10, the capacitor 31 has a function of bringing the output impedance of the peak amplifier 12 into the open state, which makes the phase shift line 526 disposed in the amplifier circuit 510 unnecessary.

That is, according to the amplifier circuit 10 according to the present embodiment, a capacitor for DC blocking that is to be disposed between an output terminal of the peak amplifier 12 and the main line 201, a phase shift line that is to be disposed between the peak amplifier 12 and the voltage supply terminal 130, and the harmonic termination circuit constituted by the inductors and the capacitors can be reduced, so that the radio frequency circuit 1 can be miniaturized while suppressing a harmonic wave of a high-output radio frequency signal.

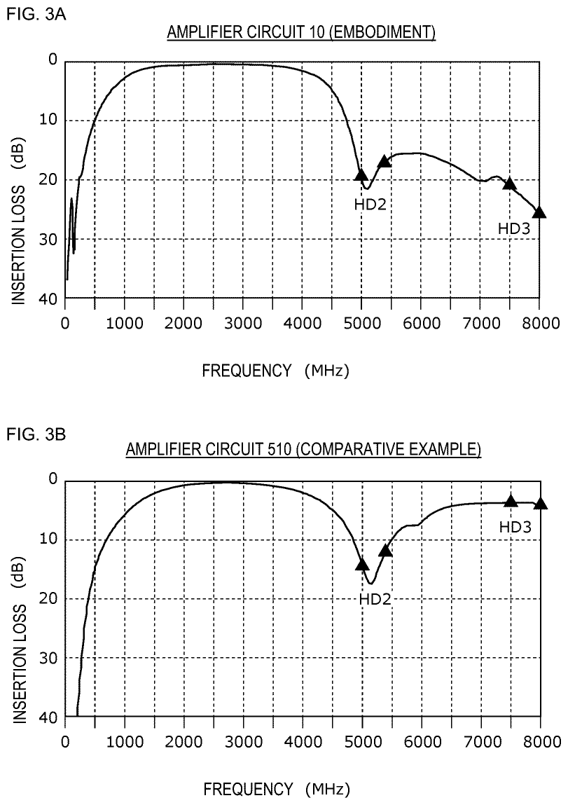

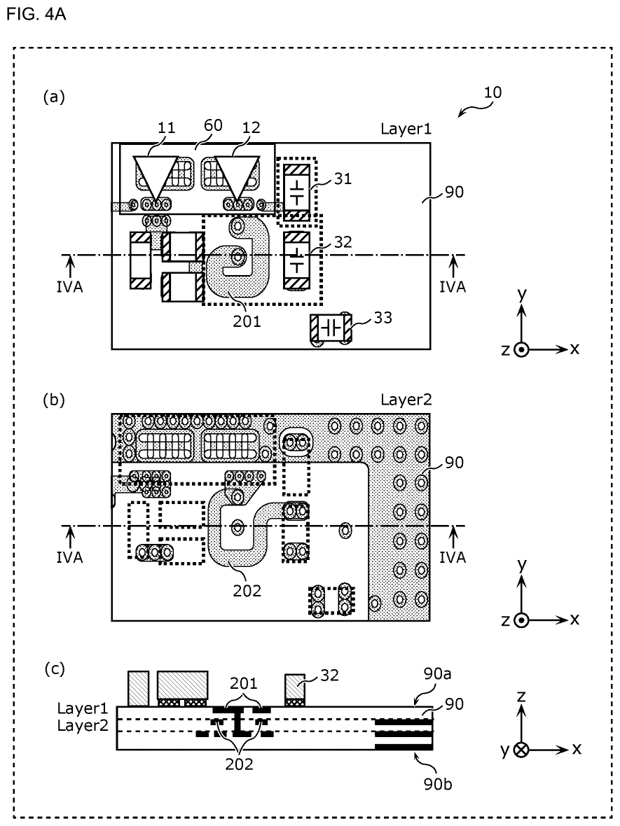

FIG. 3A is a graph showing transmission characteristics of the amplifier circuit 10 according to the embodiment. Further, FIG. 3B is a graph showing transmission characteristics of the amplifier circuit 510 according to the comparative example.

As shown in FIG. 3A and FIG. 3B, in both of the amplifier circuits 10 and 510, sufficient attenuation in a second harmonic frequency band (HD2) of a radio frequency signal can be ensured. On the other hand, in a third harmonic frequency band (HD3), larger attenuation can be ensured for the amplifier circuit 10 than for the amplifier circuit 510. This is because, in the amplifier circuit 10, the LC parallel resonant circuit constituted by the sub line 202 and the capacitor 31 becomes more capacitive and has a larger admittance as a frequency band increases.

Furthermore, an amplifier circuit in which the transmission line transformer 20 is used can have a wideband transmission characteristic as compared to an amplifier circuit in which circuit elements such as a transformer, an inductor, and a capacitor are used. From this viewpoint, in the amplifier circuit 10, the inductors and the capacitors constituting the harmonic termination circuit are reduced, and the sub line 202 of the transmission line transformer 20 is utilized. Thus, as shown in FIG. 3A and FIG. 3B, it is understood that a pass band of a fundamental wave reflects features of the transmission line transformer 20 to be wider than that of the amplifier circuit 510.

### [1.5 Component Disposition Configuration of Amplifier Circuit 10]

Next, a component disposition configuration of the amplifier circuit 10 according to the embodiment will be described.

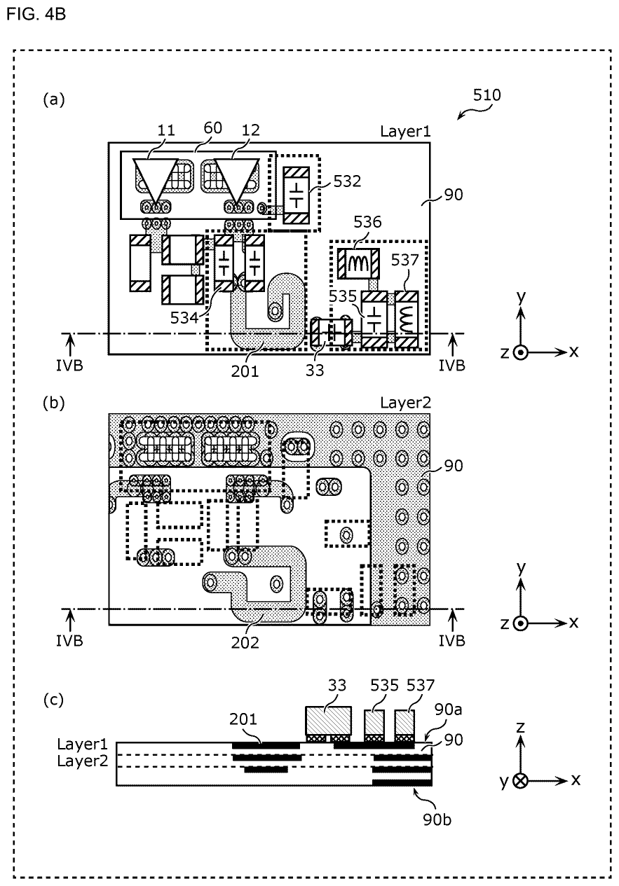

FIG. 4A includes plan views and a sectional view of the amplifier circuit 10 according to the embodiment. (a) in FIG. 4A illustrates a disposition layout of circuit components assuming a first layer (Layer 1) of a substrate 90 is viewed from the positive direction side of the z-axis, (b) in FIG. 4A illustrates a disposition layout of circuit components assuming a second layer (Layer 2) of the substrate 90 is viewed from the positive direction side of the z-axis, and (c) in FIG. 4A illustrates a sectional view taken along line IVA-IVA in (a) and (b) in FIG. 4A. In addition, in (a) in FIG. 4A, each circuit component may be marked with a mark indicating a function thereof so that a disposition relationship among the circuit components can be easily understood, but actual circuit components are not marked. In addition, in FIG. 4A, a wiring line for connecting the substrate 90 and the circuit components is not illustrated.

Note that the amplifier circuit 10 may further include a resin member covering a surface of the substrate 90 and some of the circuit components, and a shield electrode layer covering a surface of the resin member, but the resin member and the shield electrode layer are not illustrated in FIG. 4A.

The amplifier circuit 10 further has the substrate 90 in addition to the circuit configuration illustrated in FIG. 1.

The substrate 90 is a substrate in or on which the circuit components constituting the amplifier circuit 10 are mounted. As the substrate 90, for example, a low temperature co-fired ceramics (LTCC) substrate, a high temperature co-fired ceramics (HTCC) substrate, a component-embedded substrate, a substrate having a redistribution layer (RDL), a printed circuit board, or the like, each of which having a laminated structure of a plurality of dielectric layers, is used. The substrate 90 has a main surface 90a (first main surface) and a main surface 90b (second main surface) which face each other, and the first layer (Layer 1) and the second layer (Layer 2) are laminated in order from the main surface 90a (a positive side of the z-axis) toward the main surface 90b (a negative side of the z-axis).

As illustrated in (a) in FIG. 4A, a semiconductor IC 60 including the carrier amplifier 11 and the peak amplifier 12 is disposed on the main surface 90a of the substrate 90.

The semiconductor IC 60 may be formed using, for example, a complementary metal oxide semiconductor (CMOS) and may be manufactured by a silicon on insulator (SOI) process. Further, the semiconductor IC may be formed of at least one of GaAs, SiGe and GaN. Note that the semiconductor material of the semiconductor IC 60 is not limited to the above-mentioned materials. Note that at least one of the preamplifier 13, the phase shift circuit 40, and the phase shift line 25 may be included in the semiconductor IC 60.

Additionally, the main line 201 and the sub line 202 of the transmission line transformer 20 are formed at a surface or an inside of the substrate 90. As illustrated in (a) in FIG. 4A, the main line 201 is formed of a planar conductor formed at the first layer (Layer 1). Additionally, as illustrated in (b) in FIG. 4A, the sub line 202 is formed of a planar conductor formed at the second layer (Layer 2). The main line 201 and the sub line 202 at least partially overlap each other assuming viewed from a direction (z-axis direction) normal to the main surface of the substrate 90. Thus, the main line 201 and the sub line 202 are electromagnetically coupled to each other.

Note that the main line 201 and the sub line 202 may be formed at the same layer or may be formed at different layers, of the substrate 90. Further, each of the main line 201 and the sub line 202 may be formed across a plurality of layers.

Additionally, as illustrated in (a) in FIG. 4A, the capacitors 31, 32, and 33 are disposed on the main surface 90a of the substrate 90. Each of the capacitors 31 to 33 is a chip-shaped surface mount device.

Here, the capacitor 31 and the semiconductor IC 60 are adjacent to each other on the main surface 90a of the substrate 90.

According to this, a line connecting the peak amplifier 12 and the capacitor 31 can be shortened, and parasitic inductance components between the peak amplifier 12 and the LC parallel resonant circuit constituted by the capacitor 31 and the sub line 202 can be reduced, and thus it is possible to enhance a harmonic termination function of the LC parallel resonant circuit.

Note that, in addition to the circuit components included in the amplifier circuit 10, the circuit components included in the radio frequency circuit 1 may be disposed in or on the substrate 90.

Next, for comparison, a component disposition configuration of the amplifier circuit 510 according to the comparative example will be described.

FIG. 4B includes plan views and a sectional view of the amplifier circuit 510 according to the comparative example. The component disposition configuration of the amplifier circuit 510 illustrated in FIG. 4B is different from the component disposition configuration of the amplifier circuit 10 illustrated in FIG. 4A in a disposition configuration of the capacitors 33, 532, 534, and 535, the inductors 536 and 537, the main line 201, and the sub line 202. Hereinafter, the component disposition configuration of the amplifier circuit 510 will be described focusing on differences from the component disposition configuration of the amplifier circuit 10, and description of the same points will be omitted.

As illustrated in (a) in FIG. 4B, the capacitors 33, 532, 534, and 535 and the inductors 536 and 537 are disposed on the main surface 90a of the substrate 90. Each of the capacitors and the inductors is a chip-shaped surface mount device.

The main line 201 and the sub line 202 of the transmission line transformer 20 are formed on the surface or the inside of the substrate 90. As illustrated in (a) in FIG. 4B, the main line 201 is formed of a planar conductor formed at the first layer (Layer 1). Additionally, as illustrated in (b) in FIG. 4B, the sub line 202 is formed of a planar conductor formed at the second layer (Layer 2). The main line 201 and the sub line 202 at least partially overlap each other upon being viewed from the direction (z-axis direction) normal to the main surface of the substrate 90. Thus, the main line 201 and the sub line 202 are electromagnetically coupled to each other.

In the amplifier circuit 10, circuit components disposed between the semiconductor IC 60 and the capacitor 33 are the transmission line transformer 20 and the capacitors 31, 32, and 33, whereas in the amplifier circuit 510, circuit components disposed between the semiconductor IC 60 and the capacitor 33 are the transmission line transformer 20, the capacitors 33, 532, 534, and 535, and the inductors 536 and 537, and the number of circuit components is increased. Thus, in the amplifier circuit 510, areas of the circuit components disposed in or on the substrate 90 are large as compared with the amplifier circuit 10.

In other words, according to the amplifier circuit 10 according to the present embodiment, capacitors for DC blocking that are to be disposed between the output terminal of the peak amplifier 12 and the main line 201 can be reduced, a phase shift line that is to be disposed between the peak amplifier 12 and the voltage supply terminal 130 can be shortened, and the harmonic termination circuit constituted by the inductors and the capacitors can be reduced, so that the amplifier circuit 10 and the radio frequency circuit 1 can be miniaturized while suppressing a harmonic wave of a high-output radio frequency signal.

### [1.6 Component Disposition Configuration of Amplifier Circuit 10A According to Modification 1]

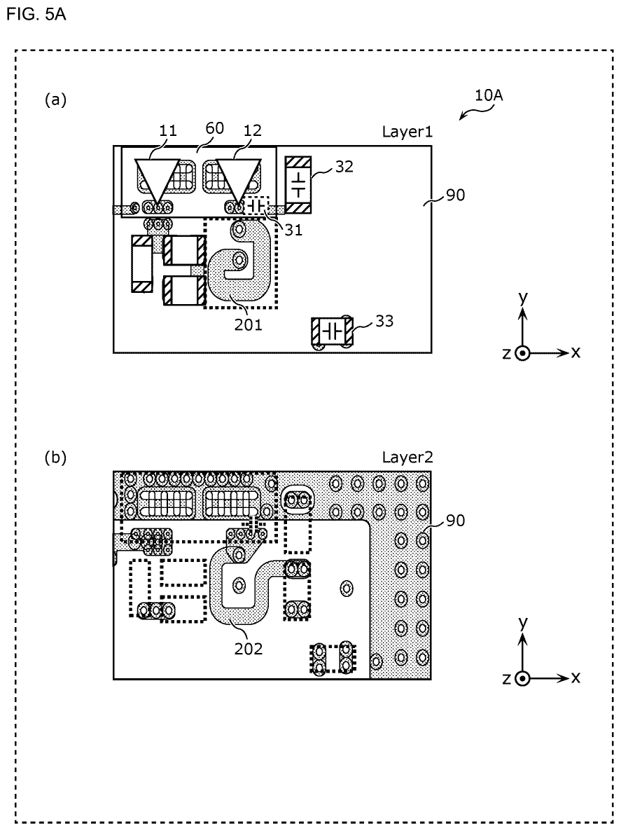

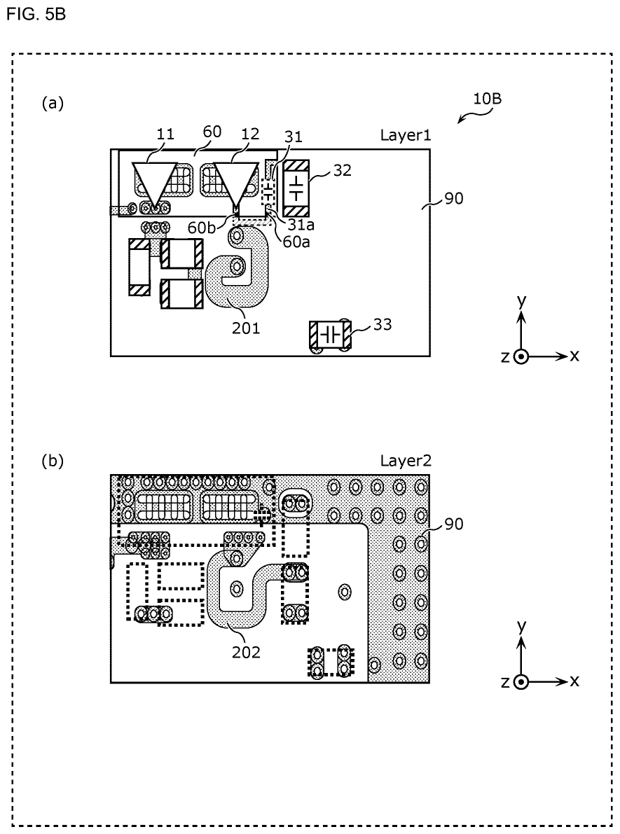

FIG. 5A includes plan views of the amplifier circuit 10A according to Modification 1. A component disposition configuration of the amplifier circuit 10A illustrated in FIG. 5A is different from the component disposition configuration of the amplifier circuit 10 illustrated in FIG. 4A only in a disposition configuration of the capacitors 31 and 32. Hereinafter, the component disposition configuration of the amplifier circuit 10A will be described focusing on differences from the component disposition configuration of the amplifier circuit 10, and description of the same points will be omitted.

As illustrated in (a) in FIG. 5A, the capacitor 31 is included in the semiconductor IC 60.

According to this, the line connecting the peak amplifier 12 and the capacitor 31 can be shortened, and the parasitic inductance components between the peak amplifier 12 and the LC parallel resonant circuit constituted by the capacitor 31 and the sub line 202 can be reduced, and thus it is possible to enhance the harmonic termination function of the LC parallel resonant circuit while miniaturizing the amplifier circuit 10A.

Additionally, as illustrated in (a) in FIG. 5A, the capacitor 32 is disposed on the main surface 90a of the substrate 90. The capacitor 32 is a chip-shaped surface mount device. The capacitor 32 and the semiconductor IC 60 are adjacent to each other on the main surface 90a of the substrate 90.

According to this, a line connecting the peak amplifier 12 and the ground can be shortened, and parasitic inductance components between the LC parallel resonant circuit constituted by the capacitor 31 and the sub line 202 and the ground and parasitic inductance components between the LC parallel resonant circuit and the peak amplifier 12 can be reduced, and thus it is possible to enhance the harmonic termination function of the LC parallel resonant circuit.

### [1.7 Component Disposition Configuration of Amplifier Circuit 10B According to Modification 2]

FIG. 5B includes plan views of the amplifier circuit 10B according to Modification 2. A component disposition configuration of the amplifier circuit 10B illustrated in FIG. 5B is different from the component disposition configuration of the amplifier circuit 10A illustrated in FIG. 5A only in a connection wiring configuration of the capacitors 31. Hereinafter, the component disposition configuration of the amplifier circuit 10B will be described focusing on differences from the component disposition configuration of the amplifier circuit 10A, and description of the same points will be omitted.

As illustrated in (a) in FIG. 5B, the capacitor 31 is included in the semiconductor IC 60. One end 31a of the capacitor 31 is connected to a wiring line formed in or on the substrate 90 with an external connection electrode 60a of the semiconductor IC 60 interposed therebetween. The output end of the peak amplifier 12 is connected to a wiring line formed in or on the substrate 90 with an external connection electrode 60b of the semiconductor IC 60 interposed therebetween. That is, in the amplifier circuit 10A according to Modification 1, the capacitor 31 and the peak amplifier 12 are directly connected to each other in the semiconductor IC 60, whereas in the amplifier circuit 10B according to the present modification, the capacitor 31 and the peak amplifier 12 are not directly connected to each other in the semiconductor IC 60. According to this, a circuit component formed outside the semiconductor IC 60 can be connected to the peak amplifier 12 and the capacitor 31 therebetween.

[1.8 Circuit Configuration of Radio frequency Circuit 1B According to Modification 3]

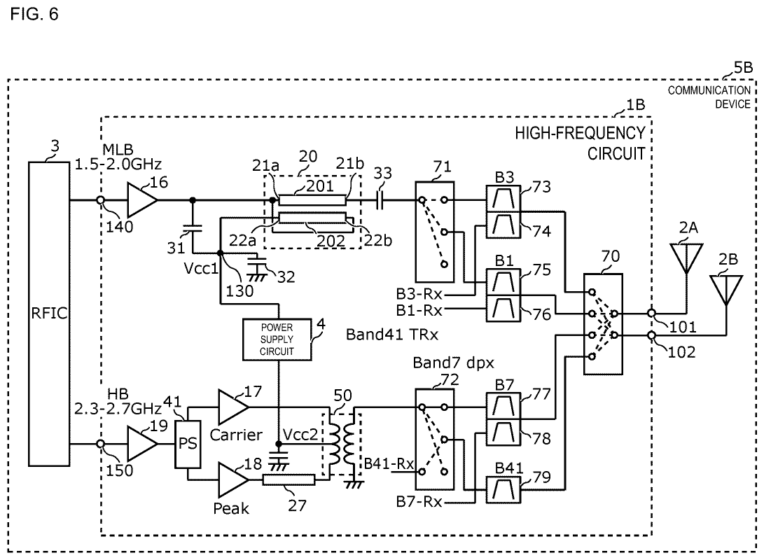

A circuit configurations of the radio frequency circuit 1B and a communication device 5B according to Modification 3 will be described with reference to FIG. 6. FIG. 6 is a circuit configuration diagram of the radio frequency circuit 1B and the communication device 5B according to Modification 3. As illustrated in the drawing, the communication device 5B according to the present modification includes the radio frequency circuit 1B, antennas 2A and 2B, and the RFIC 3.

The antenna 2A is connected to an antenna connection terminal 101, and the antenna 2B is connected to an antenna connection terminal 102. The antennas 2A and 2B transmit the radio frequency signals outputted from the radio frequency circuit 1B. The antennas 2A and 2B also receive radio frequency signals from outside and output the radio frequency signals to the radio frequency circuit 1B.

The RFIC 3 has a function as the control unit that controls the power supply voltage Vcc supplied to each amplifier included in the radio frequency circuit 1B. In particular, the RFIC 3 outputs a digital control signal to the power supply circuit 4. The power supply voltage Vcc controlled by the digital control signal is supplied from the power supply circuit 4 to each amplifier of the radio frequency circuit 1B.

Further, the RFIC 3 also has a function as the control unit that controls connection of switches 70 to 72 included in the radio frequency circuit 1B, based on a communication band (frequency band) used.

In the communication device 5B according to the present modification, the antennas 2A and 2B are not essential components.

Next, a circuit configuration of the radio frequency circuit 1B will be described. As illustrated in FIG. 6, the radio frequency circuit 1B includes an amplifier 16, a carrier amplifier 17, a peak amplifier 18, a preamplifier 19, a phase shift circuit 41, the transmission line transformer 20, a phase shift line 27, the capacitors 31, 32, and 33, a transformer 50, filters 73, 74, 75, 76, 77, 78, and 79, the switches 70, 71, and 72, signal input terminals 140 and 150, and the antenna connection terminals 101 and 102.

The signal input terminals 140 and 150 are connected to the RFIC 3. Note that each of the signal input terminals 140 and 150 and the antenna connection terminals 101 and 102 may be a metal conductor such as a metal electrode or a metal bump, or may be one point on a metal wiring line.

The power supply circuit 4 supplies a power supply voltage to the amplifier 16, the carrier amplifier 17, and the peak amplifier 18 based on a digital control signal outputted from the RFIC 3. Note that the power supply circuit 4 may be disposed outside the radio frequency circuit 1B and in the communication device 5B.

The amplifier 16 is an example of the first amplification element and amplifies a transmission signal in a first frequency band group received from the signal input terminal 140. The first frequency band group is, for example, a mid-low band (MLB: 1.5 to 2.0 GHz).

The transmission line transformer 20 has the main line 201 and the sub line 202, shifts phases at both ends of the transmission line transformer 20, and performs impedance conversion at a predetermined conversion ratio. The one end 21a of the main line 201 is connected to an output end of the amplifier 16, and the other end 21b of the main line 201 is connected to the switch 71 with the capacitor 33 interposed therebetween. The one end 22b of the sub line 202 is connected to the one end 21a of the main line 201, and the other end 22a of the sub line 202 is connected to the voltage supply terminal 130. The main line 201 and the sub line 202 are electromagnetically coupled to each other.

The capacitor 31 is an example of the first capacitor and has the one end connected to the output end of the amplifier 16 and the other end connected to the voltage supply terminal 130. The capacitor 32 is an example of the second capacitor and has the one end connected to the voltage supply terminal 130 and the other end connected to the ground. The capacitor 33 has one end connected to the transmission line transformer 20 and another end connected to the switch 71 and prevents a DC power supply voltage Vcc1 from leaking toward the switch 71 beyond the capacitor 33.

The preamplifier 19 amplifies a transmission signal in a second frequency band group received from the signal input terminal 150. The second frequency band group is, for example, a high band (HB: 2.3 to 2.7 GHz).

The phase shift circuit 41 distributes the signal RF0 outputted from the preamplifier 19 and outputs the distributed signals RF1 and RF2 to the carrier amplifier 17 and the peak amplifier 18, respectively. At that time, the phase shift circuit 41 adjusts phases of the signals RF1 and RF2. Note that the radio frequency circuit 1B need not include the preamplifier 19 or the phase shift circuit 41.

Each of the carrier amplifier 17 and the peak amplifier 18 has an amplification transistor. The amplification transistor is, for example, a bipolar transistor such as an HBT or a field-effect transistor such as a MOSFET.

The carrier amplifier 17 is an example of a third amplification element and amplifies a transmission signal in the second frequency band group inputted to the carrier amplifier 17. The carrier amplifier 17 is, for example, a class A (or class AB) amplifier circuit capable of performing amplification operation on all power levels of signals inputted to the carrier amplifier 17 and is capable of performing highly efficient amplification operation particularly in a low output region and a medium output region.

The peak amplifier 18 is an example of a fourth amplification element and amplifies a transmission signal in the second frequency band group inputted to the peak amplifier 18. The peak amplifier 18 is, for example, a class C amplifier circuit that can perform amplification operation in a region where a power level of a signal inputted to the peak amplifier 18 is high. An output impedance decreases as the power level of the signal inputted to the peak amplifier 18 increases. Thus, the peak amplifier 18 can perform amplification operation with low distortion in a high output region.

The transformer 50 is an example of a transformer and has an input side coil and an output side coil. One end of the input side coil is connected to an output end of the carrier amplifier 17. Another end of the input side coil is connected to an output end of the peak amplifier 18 with the phase shift line 27 interposed therebetween. One end of the output side coil is connected to the switch 72, and another end of the output side coil is connected to the ground. According to the transformer 50, a signal outputted from the carrier amplifier 17 and a signal outputted from the peak amplifier 18 are subjected to voltage addition, and a combined output signal is outputted to the switch 72.

The phase shift line 27 is an example of a second phase shift circuit and is, for example, a ¼ wavelength transmission line. The phase shift line 27 delays a phase of a radio frequency signal received from one end by ¼ of a wavelength and outputs the signal from another end. The one end of the phase shift line 27 is connected to the output end of the peak amplifier 18, and the other end of the phase shift line 27 is connected to the other end of the input side coil.

The switch 71 is connected to the transmission line transformer 20 with the signal output terminal 120 (not illustrated) interposed therebetween, is also connected to the filters 73 and 75, and switches between connection between the transmission line transformer 20 and the filter 73 and connection between the transmission line transformer 20 and the filter 75.

The switch 72 is connected to the transformer 50 and the filter 77 therebetween, is connected to the transformer 50 and the filter 79 therebetween, and switches between connection between the transformer 50 and the filter 77 and connection between the transformer 50 and the filter 79.

The switch 70 has a first terminal, a second terminal, a third terminal, and a fourth terminal. The first terminal is connected to the antenna connection terminal 101, the second terminal is connected to the antenna connection terminal 102, the third terminal is connected to the filters 73 and 74, and the fourth terminal is connected to the filters 77 and 78. The switch 70 switches between connection and disconnection between the first terminal and the third terminal, switches between connection and disconnection between the first terminal and the fourth terminal, switches between connection and disconnection between the second terminal and the third terminal, and switches between connection and disconnection between the second terminal and the fourth terminal. That is, the switch 70 is connected to the antenna connection terminal 101 and the filters 73 to 79 therebetween, is connected to the antenna connection terminal 102 and the filters 73 to 79 therebetween, switches between connection between the antenna connection terminal 101 and each of the filters 73 to 79, and switches between connection between the antenna connection terminal 102 and each of the filters 73 to 79.

The filter 73 is an example of a first filter, is connected to the switch 70 and the switch 71 therebetween, and includes a first band belonging to the first frequency band group in a pass band. The first band includes, for example, an uplink operating band of Band B3 for 4G-LTE or an uplink operating band (1710 to 1785 MHz) of Band n3 for 5G-NR.

The filter 74 is connected to the switch 70. A pass band of the filter 74 includes a downlink operating band of Band B3 for 4G-LTE, for example, or a downlink operating band (1805 to 1880 MHz) of Band n3 for 5G-NR.

The filter 75 is connected to the switch 70 and the switch 71 therebetween. A pass band of the filter 75 includes, for example, an uplink operating band of Band B1 for 4G-LTE or an uplink operating band (1920 to 1980 MHz) of Band n1 for 5G-NR.

The filter 76 is connected to the switch 70. A pass band of the filter 76 includes a downlink operating band of Band B1 for 4G-LTE, for example, or a downlink operating band (2110 to 2170 MHz) of Band n1 for 5G-NR.

The filter 77 is an example of a second filter, is connected to the switch 70 and the switch 72 therebetween, and includes a second band belonging to the second frequency band group in a pass band. The second band includes, for example, an uplink operating band of Band B7 for 4G-LTE or an uplink operating band (2500 to 2570 MHz) of Band n7 for 5G-NR.

The filter 78 is connected to the switch 70. A pass band of the filter 78 includes a downlink operating band of Band B7 for 4G-LTE, for example, or a downlink operating band (2620 to 2690 MHz) of Band n7 for 5G-NR.

The filter 79 is an example of the second filter and is connected to the switch 70 and the switch 72 therebetween. A pass band of the filter 79 includes, for example, Band B41 for 4G-LTE or Band n41 (2496 to 2690 MHz) for 5G-NR.

According to the above-described configuration of the radio frequency circuit 1B, a radio frequency signal in the first frequency band group being wideband can be transmitted through a transmission path having the transmission line transformer 20 having a wideband transmission characteristic, and a radio frequency signal in the second frequency band group being narrowband can be transmitted through a transmission path having the Doherty-type amplifier circuit.

### [1.9 Advantageous Effects and the Like]

As described above, the radio frequency circuit 1 according to the present embodiment includes the carrier amplifier 11, the transmission line transformer 20 having the main line 201 and the sub line 202, the signal output terminal 120, the voltage supply terminal 130, and the capacitor 31, wherein the main line 201 has the one end 21a connected to the output end of the peak amplifier 12, the main line 201 has the other end 21b connected to the signal output terminal 120, the sub line 202 has the one end 22b connected to the one end 21a of the main line 201, the sub line 202 has the other end 22a connected to the voltage supply terminal 130, and the peak amplifier 12 has the output end connected to the voltage supply terminal 130 with the capacitor 31 interposed therebetween.

According to this, capacitors for DC blocking that are to be disposed between the output end of the peak amplifier 12 and the main line 201, a phase shift line that is to be disposed between the peak amplifier 12 and the voltage supply terminal 130, and the harmonic termination circuit constituted by the inductors and the capacitors can be reduced, so that the radio frequency circuit 1 can be miniaturized while suppressing a harmonic wave of a high-output radio frequency signal.

Further, for example, the radio frequency circuit 1 may further include the capacitor 32 connected to the voltage supply terminal 130 and the ground therebetween, and a capacitance value of the capacitor 31 may be smaller than a capacitance value of the capacitor 32.

According to this, since the capacitance value of the capacitor 31 can be made relatively small, deterioration of characteristics of a fundamental wave of a radio frequency signal can be suppressed.

Further, for example, the radio frequency circuit 1 may further include the substrate 90, the peak amplifier 12 may be included in the semiconductor IC 60 disposed on the substrate 90, and the capacitor 31 may be included in the semiconductor IC 60.

According to this, the line connecting the peak amplifier 12 and the capacitor 31 can be shortened, and inductance components between the peak amplifier 12 and the LC parallel resonant circuit constituted by the capacitor 31 and the sub line 202 can be reduced, and thus it is possible to enhance the harmonic termination function of the LC parallel resonant circuit.

Further, for example, the radio frequency circuit 1 may further include the substrate 90, the peak amplifier 12 may be included in the semiconductor IC 60 disposed on the main surface 90a of the substrate 90, the capacitor 31 may be a chip-shaped component disposed on the main surface 90a, and the capacitor 31 and the semiconductor IC 60 may be adjacent to each other on the main surface 90a.

According to this, the line connecting the peak amplifier 12 and the capacitor 31 can be shortened, and the inductance components between the peak amplifier 12 and the LC parallel resonant circuit constituted by the capacitor 31 and the sub line 202 can be reduced, and thus it is possible to enhance the harmonic termination function of the LC parallel resonant circuit.

Further, for example, the radio frequency circuit 1 may further include the substrate 90, the peak amplifier 12 may be included in the semiconductor IC 60 disposed on the substrate 90, the capacitor 31 may be included in the semiconductor IC 60, the capacitor 32 may be a chip-shaped component disposed on the main surface 90a, and the capacitor 32 and the semiconductor IC 60 may be adjacent to each other on the main surface 90a.

According to this, the line connecting the peak amplifier 12 and the ground can be shortened, and inductance components between the LC parallel resonant circuit constituted by the capacitor 31 and the sub line 202 and the ground and inductance components between the LC parallel resonant circuit and the peak amplifier 12 can be reduced, and thus it is possible to enhance the harmonic termination function of the LC parallel resonant circuit.

For example, the radio frequency circuit 1 may further include the carrier amplifier 11 and the phase shift line 25 having the one end connected to the output end of the carrier amplifier 11 and the other end connected to the output end of the peak amplifier 12.

According to this, a radio frequency signal can be transmitted through a transmission path having the carrier amplifier 11 and the peak amplifier 12 of a Doherty-type.

Further, for example, the radio frequency circuit 1B may include the amplifier 16, the transmission line transformer 20, the capacitor 31, the carrier amplifier 17 and the peak amplifier 18, the phase shift line 27, the transformer 50 having the input side coil and the output side coil, the filter 73 including the first band in the pass band, the filter 77 including the second band in the pass band, and the switch 70 that has the first terminal, the second terminal, the third terminal, and the fourth terminal, switches between connection and disconnection between the first terminal and the third terminal, switches between connection and disconnection between the first terminal and the fourth terminal, switches between connection and disconnection between the second terminal and the third terminal, and switches between connection and disconnection between the second terminal and the fourth terminal, the transmission line transformer 20 may be connected to one end of the filter 73, another end of the filter 73 may be connected to the third terminal, the output end of the carrier amplifier 17 may be connected to the one end of the input side coil, the output end of the peak amplifier 18 may be connected to the one end of the phase shift line 27, the other end of the phase shift line 27 may be connected to the other end of the input side coil, the one end of the output side coil may be connected to one end of the filter 77, and another end of the filter 77 may be connected to the fourth terminal.

According to this, a radio frequency signal in the first frequency band group being wideband including the first band can be transmitted through a transmission path having the transmission line transformer 20 having a wideband transmission characteristic, and a radio frequency signal in the second frequency band group being narrowband including the second band can be transmitted through a transmission path having the Doherty-type amplifier circuit.

Further, the communication device 5 according to the present embodiment includes the RFIC 3 that processes a radio frequency signal and the radio frequency circuit 1 that transmits a radio frequency signal between the RFIC 3 and the antenna 2.

According to this, the effect of the radio frequency circuit 1 can be achieved in the communication device 5.

### Other Embodiments and the Like

Although the radio frequency circuit and the communication device according to the embodiment of the present disclosure have been described above with reference to the embodiment and the modifications, the radio frequency circuit and the communication device according to the present disclosure are not limited to the above-described embodiment and modifications. The present disclosure also includes other embodiments achieved by combining any components in the above-described embodiment and modifications, modifications obtained by making various modifications to the above-described embodiment and modifications that can be conceived by those skilled in the art without departing from the spirit of the present disclosure, and various devices incorporating the above-described radio frequency circuit and communication device.

For example, in the radio frequency circuits and the communication devices according to the above-described embodiment and the modifications, other circuit elements, wiring lines, and the like may be inserted into a path connecting the circuit elements and the signal paths disclosed in the drawings.

The features of the radio frequency circuit and the communication device described based on the above embodiment will be described below.

<1>

A radio frequency circuit, comprising:
a first amplification element;
a transmission line transformer having a main line and a sub line;
a signal output terminal;
a voltage supply terminal; and
a first capacitor,
wherein one end of the main line is connected to an output end of the first amplification element, and another end of the main line is connected to the signal output terminal,
one end of the sub line is connected to the one end of the main line, and another end of the sub line is connected to the voltage supply terminal, and
the output end of the first amplification element is connected to the voltage supply terminal with the first capacitor interposed therebetween.

<2>

The radio frequency circuit according to <1> further comprising a second capacitor that is connected to the voltage supply terminal and a ground therebetween,
wherein a capacitance value of the first capacitor is smaller than a capacitance value of the second capacitor.

<3>

The radio frequency circuit according to <1> or <2> further comprising a substrate,
wherein the first amplification element is included in a semiconductor IC disposed on the substrate, and
the first capacitor is included in the semiconductor IC.

<4>

The radio frequency circuit according to <1> or <2> further comprising a substrate,
wherein the first amplification element is included in a semiconductor IC disposed on a main surface of the substrate,
the first capacitor is a chip-shaped component disposed on the main surface, and
the first capacitor and the semiconductor IC are adjacent to each other on the main surface.

<5>

The radio frequency circuit according to <2> further comprising a substrate,
wherein the first amplification element is included in a semiconductor IC disposed on a main surface of the substrate,
the first capacitor is included in the semiconductor IC,
the second capacitor is a chip-shaped component disposed on the main surface, and
the second capacitor and the semiconductor IC are adjacent to each other on the main surface.

<6>

The radio frequency circuit according to any one of <1> to <5> further comprising:
a second amplification element; and
a first phase shift circuit having one end connected to an output end of the second amplification element and another end connected to the output end of the first amplification element.

<7>

The radio frequency circuit according to any one of <1> to <5> further comprising:
a third amplification element and a fourth amplification element;
a second phase shift circuit;
a transformer having an input side coil and an output side coil;
a first filter including a first band in a pass band;
a second filter including a second band in a pass band; and
a switch having a first terminal, a second terminal, a third terminal, and a fourth terminal and configured to switch between connection and disconnection between the first terminal and the third terminal, switch between connection and disconnection between the first terminal and the fourth terminal, switch between connection and disconnection between the second terminal and the third terminal, and switch between connection and disconnection between the second terminal and the fourth terminal,
wherein the signal output terminal is connected to one end of the first filter, and another end of the first filter is connected to the third terminal,
an output end of the third amplification element is connected to one end of the input side coil,
an output end of the fourth amplification element is connected to one end of the second phase shift circuit, and another end of the second phase shift circuit is connected to another end of the input side coil, and
one end of the output side coil is connected to one end of the second filter, and another end of the second filter is connected to the fourth terminal.

<8>

A communication device comprising:
a signal processing circuit configured to process a radio frequency signal; and
the radio frequency circuit according to any one of <1> to <7> configured to transmit the radio frequency signal between the signal processing circuit and an antenna.

### Industrial Applicability

The present disclosure can be widely used in communication devices such as mobile phones as a radio frequency circuit disposed in a front end unit supporting multiband.

### REFERENCE SIGNS LIST

1, 1B RADIO FREQUENCY CIRCUIT
2, 2A, 2B ANTENNA
3 RF SIGNAL PROCESSING CIRCUIT (RFIC)
4 POWER SUPPLY CIRCUIT
5, 5B COMMUNICATION DEVICE
10, 10A, 10B, 510 AMPLIFIER CIRCUIT
11, 17 CARRIER AMPLIFIER
12, 18 PEAK AMPLIFIER
13, 19 PREAMPLIFIER
16 AMPLIFIER
20 TRANSMISSION LINE TRANSFORMER
21a, 22b, 31a ONE END
21b, 22a ANOTHER END
25, 27, 526 PHASE SHIFT LINE
31, 32, 33, 532, 534, 535 CAPACITOR
40, 41 PHASE SHIFT CIRCUIT
50 TRANS FORMER
60 SEMICONDUCTOR IC
60a, 60b EXTERNAL CONNECTION ELECTRODE
70, 71, 72, 81, 84 SWITCH
73, 74, 75, 76, 77, 78, 79, 82, 83 FILTER
90 SUBSTRATE
90a, 90b MAIN SURFACE
100, 101, 102 ANTENNA CONNECTION TERMINAL
110, 140, 150 SIGNAL INPUT TERMINAL
120 SIGNAL OUTPUT TERMINAL
130 VOLTAGE SUPPLY TERMINAL
201 MAIN LINE
202 SUB LINE
536, 537 INDUCTOR

1. A radio frequency circuit, comprising:
a first amplification element;
a transmission line transformer having a main line and a sub line;
a signal output terminal;
a voltage supply terminal; and
a first capacitor,
wherein one end of the main line is connected to an output end of the first amplification element, and another end of the main line is connected to the signal output terminal,
one end of the sub line is connected to the one end of the main line, and another end of the sub line is connected to the voltage supply terminal, and
the output end of the first amplification element is connected to the voltage supply terminal with the first capacitor interposed therebetween.

2. The radio frequency circuit according to claim 1 further comprising a second capacitor that is connected to the voltage supply terminal and a ground therebetween,
wherein a capacitance value of the first capacitor is smaller than a capacitance value of the second capacitor.

3. The radio frequency circuit according to claim 2 further comprising a substrate,
wherein the first amplification element is included in a semiconductor IC disposed on the substrate, and
the first capacitor is included in the semiconductor IC.

4. The radio frequency circuit according to claim 2 further comprising a substrate,
wherein the first amplification element is included in a semiconductor IC disposed on a main surface of the substrate,
the first capacitor is a chip-shaped component disposed on the main surface, and
the first capacitor and the semiconductor IC are adjacent to each other on the main surface.

5. The radio frequency circuit according to claim 2 further comprising a substrate,
wherein the first amplification element is included in a semiconductor IC disposed on a main surface of the substrate,
the first capacitor is included in the semiconductor IC,
the second capacitor is a chip-shaped component disposed on the main surface, and
the second capacitor and the semiconductor IC are adjacent to each other on the main surface.

6. The radio frequency circuit according to claim 5 further comprising:
a second amplification element; and
a first phase shift circuit having one end connected to an output end of the second amplification element and another end connected to the output end of the first amplification element.

7. The radio frequency circuit according to claim 5 further comprising:
a third amplification element and a fourth amplification element;
a second phase shift circuit;
a transformer having an input side coil and an output side coil;
a first filter including a first band in a pass band;
a second filter including a second band in a pass band; and
a switch having a first terminal, a second terminal, a third terminal, and a fourth terminal and configured to switch between connection and disconnection between the first terminal and the third terminal, switch between connection and disconnection between the first terminal and the fourth terminal, switch between connection and disconnection between the second terminal and the third terminal, and switch between connection and disconnection between the second terminal and the fourth terminal,
wherein the signal output terminal is connected to one end of the first filter, and another end of the first filter is connected to the third terminal,
an output end of the third amplification element is connected to one end of the input side coil,
an output end of the fourth amplification element is connected to one end of the second phase shift circuit, and another end of the second phase shift circuit is connected to another end of the input side coil, and
one end of the output side coil is connected to one end of the second filter, and another end of the second filter is connected to the fourth terminal.

8. The radio frequency circuit according to claim 1 further comprising a substrate,
wherein the first amplification element is included in a semiconductor IC disposed on the substrate, and
the first capacitor is included in the semiconductor IC.

9. The radio frequency circuit according to claim 1 further comprising a substrate,
wherein the first amplification element is included in a semiconductor IC disposed on a main surface of the substrate,
the first capacitor is a chip-shaped component disposed on the main surface, and
the first capacitor and the semiconductor IC are adjacent to each other on the main surface.

10. The radio frequency circuit according to claim 1 further comprising:
a second amplification element; and
a first phase shift circuit having one end connected to an output end of the second amplification element and another end connected to the output end of the first amplification element.

11. The radio frequency circuit according to claim 1 further comprising:
a third amplification element and a fourth amplification element;
a second phase shift circuit;
a transformer having an input side coil and an output side coil;
a first filter including a first band in a pass band;
a second filter including a second band in a pass band; and
a switch having a first terminal, a second terminal, a third terminal, and a fourth terminal and configured to switch between connection and disconnection between the first terminal and the third terminal, switch between connection and disconnection between the first terminal and the fourth terminal, switch between connection and disconnection between the second terminal and the third terminal, and switch between connection and disconnection between the second terminal and the fourth terminal,
wherein the signal output terminal is connected to one end of the first filter, and another end of the first filter is connected to the third terminal,
an output end of the third amplification element is connected to one end of the input side coil,
an output end of the fourth amplification element is connected to one end of the second phase shift circuit, and another end of the second phase shift circuit is connected to another end of the input side coil, and
one end of the output side coil is connected to one end of the second filter, and another end of the second filter is connected to the fourth terminal.

12. The radio frequency circuit according to claim 2 further comprising:
a second amplification element; and
a first phase shift circuit having one end connected to an output end of the second amplification element and another end connected to the output end of the first amplification element.

13. The radio frequency circuit according to claim 2 further comprising:
a third amplification element and a fourth amplification element;
a second phase shift circuit;
a transformer having an input side coil and an output side coil;
a first filter including a first band in a pass band;
a second filter including a second band in a pass band; and
a switch having a first terminal, a second terminal, a third terminal, and a fourth terminal and configured to switch between connection and disconnection between the first terminal and the third terminal, switch between connection and disconnection between the first terminal and the fourth terminal, switch between connection and disconnection between the second terminal and the third terminal, and switch between connection and disconnection between the second terminal and the fourth terminal,
wherein the signal output terminal is connected to one end of the first filter, and another end of the first filter is connected to the third terminal,
an output end of the third amplification element is connected to one end of the input side coil,
an output end of the fourth amplification element is connected to one end of the second phase shift circuit, and another end of the second phase shift circuit is connected to another end of the input side coil, and
one end of the output side coil is connected to one end of the second filter, and another end of the second filter is connected to the fourth terminal.

14. The radio frequency circuit according to claim 3 further comprising:
a second amplification element; and
a first phase shift circuit having one end connected to an output end of the second amplification element and another end connected to the output end of the first amplification element.

15. The radio frequency circuit according to Claim further comprising:
a third amplification element and a fourth amplification element;
a second phase shift circuit;
a transformer having an input side coil and an output side coil;
a first filter including a first band in a pass band;
a second filter including a second band in a pass band; and
a switch having a first terminal, a second terminal, a third terminal, and a fourth terminal and configured to switch between connection and disconnection between the first terminal and the third terminal, switch between connection and disconnection between the first terminal and the fourth terminal, switch between connection and disconnection between the second terminal and the third terminal, and switch between connection and disconnection between the second terminal and the fourth terminal,
wherein the signal output terminal is connected to one end of the first filter, and another end of the first filter is connected to the third terminal,
an output end of the third amplification element is connected to one end of the input side coil,
an output end of the fourth amplification element is connected to one end of the second phase shift circuit, and another end of the second phase shift circuit is connected to another end of the input side coil, and
one end of the output side coil is connected to one end of the second filter, and another end of the second filter is connected to the fourth terminal.

16. The radio frequency circuit according to claim 4 further comprising:
a second amplification element; and
a first phase shift circuit having one end connected to an output end of the second amplification element and another end connected to the output end of the first amplification element.

17. The radio frequency circuit according to claim 4 further comprising:
a third amplification element and a fourth amplification element;
a second phase shift circuit;
a transformer having an input side coil and an output side coil;
a first filter including a first band in a pass band;
a second filter including a second band in a pass band; and
a switch having a first terminal, a second terminal, a third terminal, and a fourth terminal and configured to switch between connection and disconnection between the first terminal and the third terminal, switch between connection and disconnection between the first terminal and the fourth terminal, switch between connection and disconnection between the second terminal and the third terminal, and switch between connection and disconnection between the second terminal and the fourth terminal,
wherein the signal output terminal is connected to one end of the first filter, and another end of the first filter is connected to the third terminal,
an output end of the third amplification element is connected to one end of the input side coil,
an output end of the fourth amplification element is connected to one end of the second phase shift circuit, and another end of the second phase shift circuit is connected to another end of the input side coil, and
one end of the output side coil is connected to one end of the second filter, and another end of the second filter is connected to the fourth terminal.

18. A communication device comprising:
a signal processing circuit configured to process a radio frequency signal; and
the radio frequency circuit according to claim 1 configured to transmit the radio frequency signal between the signal processing circuit and an antenna.

19. A communication device comprising:
a signal processing circuit configured to process a radio frequency signal; and
the radio frequency circuit according to claim 2 configured to transmit the radio frequency signal between the signal processing circuit and an antenna.

20. A communication device comprising:
a signal processing circuit configured to process a radio frequency signal; and
the radio frequency circuit according to claim 3 configured to transmit the radio frequency signal between the signal processing circuit and an antenna.
